(19) United States
(12) Patent Application Publication
(10) Pub. No.: US 2026/0198252 A1
(43) Pub. Date: Jul. 9, 2026

(54) ANNEALING APPARATUS AND METHOD FOR OPERATING THE ANNEALING APPARATUS

(71) Applicant: National Tsing Hua University, Hsinchu City (TW)

(72) Inventors: Po-Wen CHIU, Hsinchu City (TW); Jui-Kang YEN, Zhubei City (TW)

(21) Appl. No.: 19/008,818

(22) Filed: Jan. 3, 2025

(51) Int. Cl. H01L 21/67; H01L 21/324

(52) U.S. Cl. CPC H10P 72/0436; H10P 95/90

(57) ABSTRACT

An annealing apparatus includes a chamber, a base disposed in the chamber for supporting a substrate, a heating set that includes at least a first subset and a second subset each subset configured to correspond to different parts of the substrate, and a power supply and control module that activates the first subset thereby switching the first subset to an activated state and heat the corresponding parts of the substrate, deactivates the first subset, activates the second subset thereby switching the second subset to the activated state and heat the corresponding parts, and deactivates the second subset.

### FIELD

The disclosure relates to an annealing apparatus and a method for operating the annealing apparatus.

### BACKGROUND

In the field of semiconductor manufacturing, a rapid thermal process such as flash lamp annealing enables a material (e.g., a wafer) to be heated rapidly via a high intensity burst of energy. FIG. 1 illustrates a conventional flash lamp annealing apparatus. The flash lamp annealing apparatus includes a chamber, a base disposed in the chamber to place a sample (e.g., a wafer) thereon, a plurality of flash lamps disposed above the base (and therefore above the wafer), external controlling circuitry connected to the flash lamps for controlling the operations of the flash lamps. In the example of FIG. 1, the flash lamps may be embodied using Xenon flash lamps. Additionally, based on different configurations, different elements may be included in the flash lamp annealing apparatus.

FIG. 2 is a circuit diagram illustrating the external controlling circuitry for the flash lamp annealing apparatus, which includes a power switch connected to a power supply, an LC network that includes a plurality of capacitors and inductors, a switch that is operable to switch between a closed state, in which the power supply charges the capacitors included in the LC network, and an open state, in which the capacitors discharge the electrical energy stored therein through an ignitor to power the flash lamps connected in series, so as to cause the flash lamps to emit a burst of energy to heat a surface of the sample. It is noted that based on different configurations, different elements may be included in the external controlling circuitry.

It is noted that as the technology of processes of semiconductor advances, the requirement of the temperature for heating the surface may increase, causing the requirement of the capacitance of the LC network to also increase, which results in an increase of the size of the external controlling circuitry. Also, for wafers with larger areas, the thermal stress induced from the heating on the surface of the wafer may cause the wafer to bend, which may cause defects on transistors formed on the wafer.

### SUMMARY

It is desired to address some of the issues associated with the flash lamp annealing process, for example, the requirement of an excessive amount of capacitance involved in the process and the thermal stress induced from the heating.

Therefore, an object of the disclosure is to provide an annealing apparatus that can alleviate at least one of the drawbacks of the prior art as mentioned above.

According to one embodiment of the disclosure, the annealing apparatus includes a chamber, a base disposed in the chamber for supporting a substrate, a heating set disposed in the chamber above the base, and a power supply and control module connected to the heating set and configured to control its operations. The heating set includes at least a first subset and a second subset, each subset configured to correspond to different parts of the substrate disposed on the base. The power supply and control module is configured to:
activate the first subset of the heating set, thereby switching the first subset to an activated state to heat the corresponding parts of the substrate,
deactivate the first subset of the heating set, thereby switching the first subset to a standby state to stop heating the corresponding parts of the substrate, activate the second subset of the heating set, thereby switching the second subset to an activated state to heat the corresponding parts of the substrate, and
deactivate the second subset of the heating set, thereby switching the second subset to a standby state to stop heating the corresponding parts of the substrate.

Specifically, activating and deactivating of the first subset are controlled by providing a pulse signal to the first subset, and activating and deactivating of the second subset are controlled by providing another pulse signal to the second subset.

Another object of the disclosure is to provide a method for operating the above-mentioned annealing apparatus for performing a flash lamp annealing operation.

According to one embodiment of the disclosure, the method for is operating an annealing apparatus. The annealing apparatus includes a chamber, a base disposed in the chamber for supporting a substrate, a heating set disposed in the chamber and above the base and including at least a first subset and a second subset and a power supply and control module connected to the heating set to control its operation. Each subset corresponds to different parts of the substrate disposed on the base. The method is implemented by the power supply and control module and includes:
activating the first subset of the heating set to switch the first subset to switch to an activated state and heat the parts of the substrate corresponding to the first subset;
deactivating the first subset of the heating set to switch the first subset to a standby state and stop heating the parts of the substrate corresponding to the first subset;
activating the second subset of the heating set to switch the second subset to an activated state and heat the parts of the substrate corresponding to the second subset; and
deactivating the second subset of the heating set to switch the second subset to a standby state and stop heating the parts of the substrate that corresponding to the second subset.

Specifically, the consecutive operations of activating and deactivating the first subset are performed by providing a pulse signal to the first subset, and the consecutive operations of activating and deactivating the second subset are performed by providing another pulse signal to the second subset.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

Throughout the disclosure, the term “coupled to” or “connected to” may refer to a direct connection among a plurality of electrical apparatus/devices/equipment via an electrically conductive material (e.g., an electrical wire), or an indirect connection between two electrical apparatus/devices/equipment via another one or more apparatus/devices/equipment, or wireless communication.

FIG. 1 illustrates a conventional flash lamp annealing apparatus.

FIG. 2 is a circuit diagram illustrating the external controlling circuitry for the flash lamp annealing apparatus.

FIG. 3 illustrates an annealing apparatus according to one embodiment of the disclosure.

FIG. 4 is a circuit diagram illustrating an exemplary power supply and control module for the annealing apparatus according to one embodiment of the disclosure.

FIG. 5 is a flow chart illustrating steps of a method for operating an annealing apparatus according to one embodiment of the disclosure.

FIG. 6 is a top view illustrating an exemplary arrangement of a first subset, a second subset and a third subset of a heating set disposed to be above a substrate.

FIG. 7 illustrates an exemplary configuration of the heating set according to one embodiment of the disclosure.

FIG. 8 illustrates an exemplary arrangement of the flash lamps of the heating set.

FIG. 9 is a line graph illustrating the relative intensity of light emitted onto the surface of the substrate by the heating set of FIG. 8.

FIG. 10 illustrates another exemplary arrangement of the flash lamps of the heating set.

FIG. 11 is a line graph illustrating the relative intensity of light emitted onto the surface of the substrate by the heating set of FIG. 10.

FIG. 12 illustrates a side siew of an exemplary heating set that includes one flash lamp for the purpose of illustration.

FIG. 13 illustrates an exemplary configuration of the heating set and a secondary optical adjustment module according to one embodiment of the disclosure.

FIG. 14 is a line graph illustrating the relative intensity of light emitted onto the surface of the substrate by the heating set and the secondary optical adjustment module of FIG. 12.

FIG. 15 illustrates an exemplary configuration of the heating set and the secondary optical adjustment module according to one embodiment of the disclosure.

FIG. 16 illustrates the relative intensity of light emitted onto the surface of the substrate by the heating set and the secondary optical adjustment module of FIG. 15.

FIG. 17 is a top view illustrating the heating set and the secondary optical adjustment module of FIG. 15 disposed above the substrate.

FIG. 18 is a plot illustrating a set of electrical characteristics of an exemplary flash lamps used in the embodiments of the disclosure.

FIGS. 19 to 21 illustrates different waveforms of a pulse signal generated by the heating set.

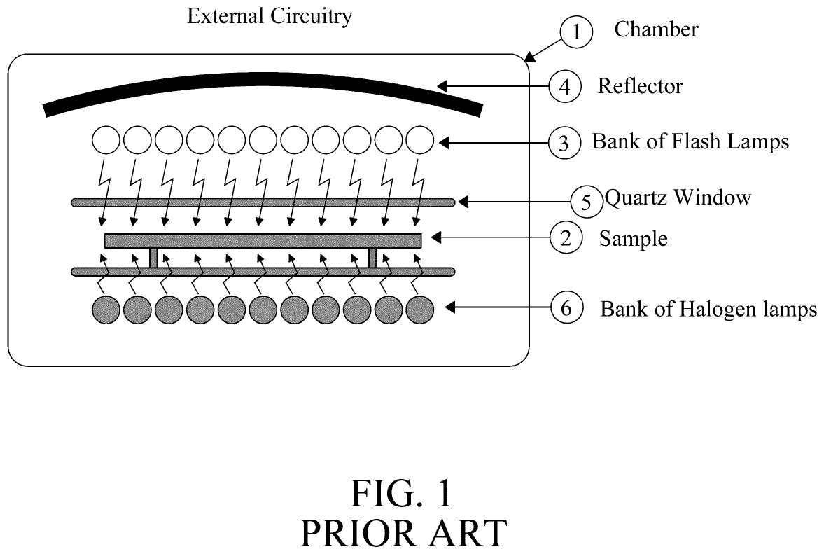

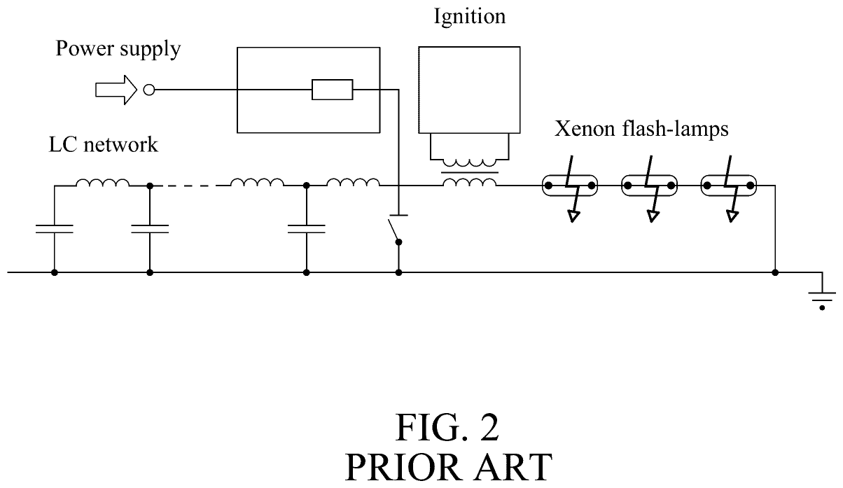

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

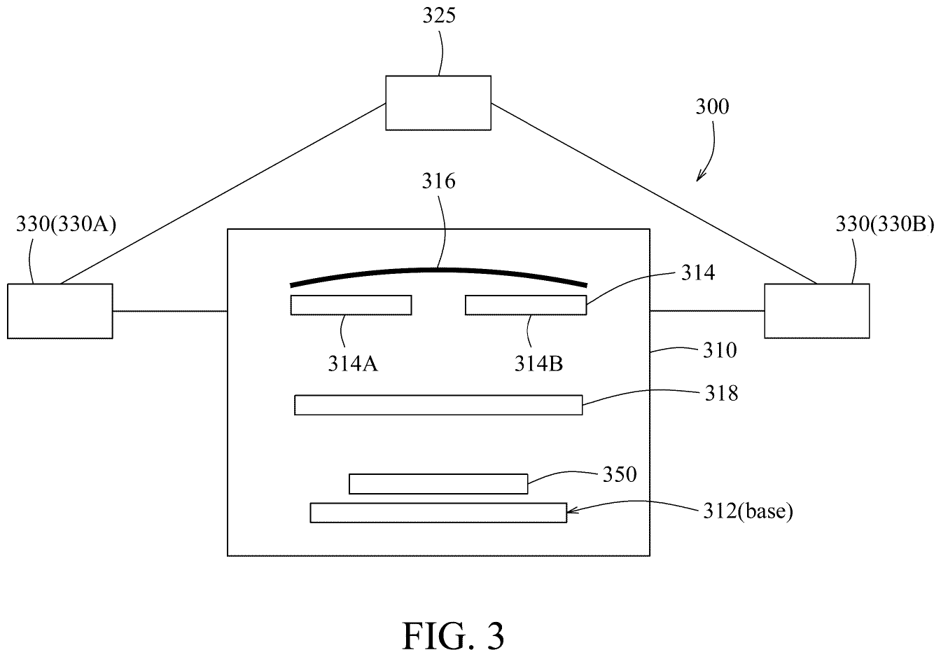

FIG. 3 illustrates an annealing apparatus 300 according to one embodiment of the disclosure. In the embodiment of FIG. 3, the annealing apparatus 300 includes a chamber 310, a base 312 disposed in the chamber 310 for supporting a substrate 350 thereon, a heating set 314 that is disposed in the chamber 300 above the base 312 (and is also above the substrate 350 when the substrate 350 is disposed on the base 312), and a power supply and control module 330 connected to the heating set 314 and configured to control the operations of the heating set 314.

In some embodiments, the annealing apparatus 300 may further include a reflector 316 disposed above the heating set 314, a quartz window 318 disposed between the reflector 316 and the substrate 350, and a bottom lamp module 320 disposed below the base 312.

The heating set 314 may be embodied using a plurality of flash lamps. In embodiments, the flash lamps may be embodied using xenon flash lamps or other suitable flash lamps.

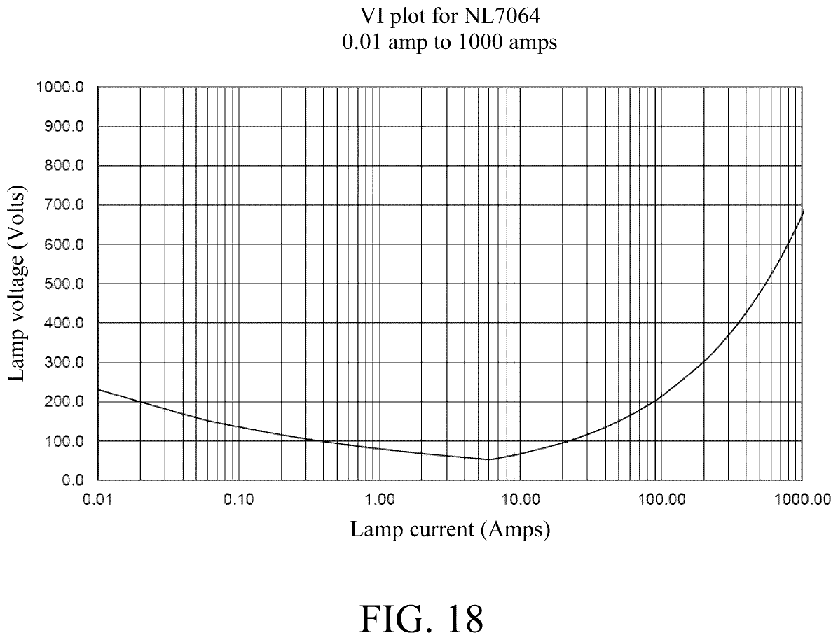

The flash lamp may be configured to have different electrical characteristics based on different applications. One exemplary set of electrical characteristics for the flash lamps used in the embodiments of the disclosure is as shown in FIG. 18. In the example of FIG. 18, a maximum electrical current of 1000 amperes is supported.

In some embodiments, the heating set 314 is constituted by a number of subsets, each subset including at least one flash lamp. In the embodiment of FIG. 3, the heating set 314 includes a first subset 314A and a second subset 314B.

The first subset 314A and the second subset 314B are disposed spaced apart from each other, to correspond with different parts of the substrate 350. In one embodiment, the first subset 314A includes a flash lamp disposed to correspond with one half of the substrate 350 (i.e., above the one half of the substrate 350 and therefore able to heat a surface of the one half of the substrate 350), and the second subset 314B includes a flash lamp disposed to correspond with the other half of the substrate 350. Each of the first subset 314A and the second subset 314B is connected to the power supply and control module 330.

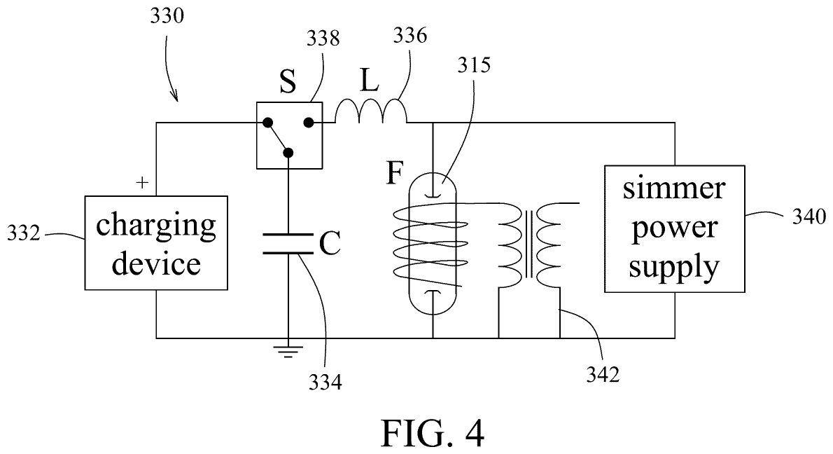

FIG. 4 is a circuit diagram illustrating an exemplary power supply and control module 330 according to one embodiment of the disclosure. In the embodiment of FIG. 4, the power supply and control module 330 includes: a charging device 332; a capacitor 334; an inductor 336; a switch 338 that is connected to the charging device 332, the capacitor 334 and the inductor 336 and that is operable between a first position, in which the charging device 332 is connected to the capacitor 334 to charge the capacitor 334, and a second position, in which the capacitor 334 is connected to the inductor 336; a simmer power supplying component 340 connected to the heating set 314 (FIG. 4 showing a flash lamp 315 included in the heating set 314 instead of the heating set 314 itself); and a transformer 342 connected to a wire which is wrapped around the heating set 314. It is noted that in some embodiments, additional power supply and control modules 330 similar to the one depicted in FIG. 4 may be provided, each being connected to one flash lamp of each of the subsets (e.g., the first subset 314A and the second subset 314B) included in the heating set 314. This configuration may be employed in the cases that a larger number of flash lamps are provided.

In use, prior to implementing an annealing operation on the substrate 350, the switch 338 is controlled to be in the first position, and the charging device 332 charges the capacitor 334.

In the case that it is to initiate the annealing operation on the substrate 350, the switch 338 is controlled to switch to the second position. As a result, the capacitor 334 is connected to the flash lamp 315, and the electrical energy stored in the capacitor 334 is transferred to the flash lamp 315, thereby activating the first subset 314A or the second subset 314B of the heating set 314. In embodiments, the switch 338 may be controlled to switch to the second position for a short period of time and then switch back to the first position. As a result, the power supply and control module 330 is controlled to provide a pulse signal (e.g., a high voltage pulse) to the flash lamp 315 for igniting the same. In response, the flash lamp 315 is ignited and enters an activated state (e.g., maintained by a simmer current provided by the simmer power supplying component 340), releasing energy to heat the substrate 350 below.

In the embodiment of FIG. 3, the first subset 314A and the second subset 314B in the heating set 314 are activated separately, that is, the first subset 314A is activated while the second subset 314B is deactivated, and the first subset 314A is deactivated while the second subset 314B is activated. Specifically, each of the first subset 314A and the second subset 314B includes one flash lamp, and the power supply and control module 330 is connected to the first subset 314A and the second subset 314B via a switch 325 that is configured to connect the power supply and control module 330 to the first subset and the second subset of the heating set. The switch unit 325 can be operated between a first state in which the power supply and control module 330 is connected to the flash lamp of the first subset 314A, and a second state in which the power supply and control module 330 is connected to the flash lamp of the second subset 314B.

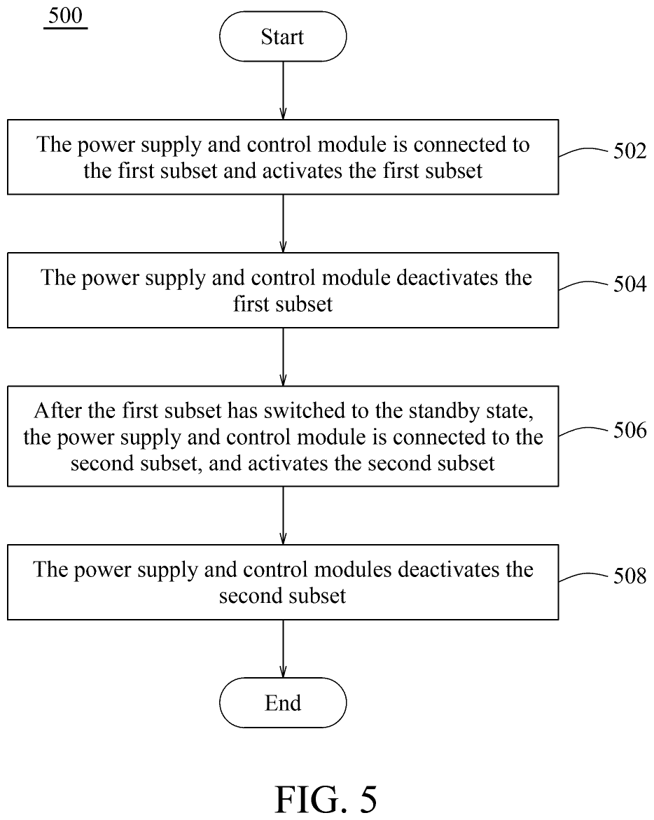

FIG. 5 is a flow chart illustrating steps of a method for operating an annealing apparatus according to one embodiment of the disclosure. In the embodiment of FIG. 5, the annealing apparatus may be embodied using the annealing apparatus 300 as shown in FIG. 3.

In use, a substrate 350 (e.g., a wafer) is placed on the base 312 below the heating set 314 for performing a flash lamp annealing operation. After the flash lamp annealing operation is initiated, in step 502, the power supply and control module 330 is connected via the switch 325 to the first subset 314A, and activates the first subset 314A of the heating set 314 (i.e., control the switch 338 of the power supply and control module 330 to switch to the second position), so as to cause the first subset 314A of the heating set 314 to switch to an activated state (i.e., to ignite the flash lamp 315 of the first subset 314A) and in turn heat the parts of the substrate 350 that correspond with the first subset 314A (i.e., below the first subset 314A). That is to say, the power supply and control module 330 activates first subset 314A of the heating set 314, thereby switching the first subset 314A to the activated state to heat the corresponding parts of the substrate 350.

Then, in step 504, the power supply and control module 330 deactivates the first subset 314A of the heating set 314 (i.e., the switch 338 is switched to the first position), so as to cause the first subset 314A of the heating set 314 to switch to a standby state (i.e., cause the flash lamp 315 to turn off) and stop heating the parts of the substrate that correspond with the first subset 314A. That is to say, the power supply and control module 330 deactivates the first subset 314A of the heating set 314, thereby switching the first subset 314A to the standby state to stop heating the corresponding parts of the substrate 350.

It is noted that the consecutive execution of steps 502 and 504 is equivalent to providing a pulse signal fed to the first subset 314A to heat the corresponding parts of the substrate 350.

In some embodiments, a duration between rising and falling edges of each pulse of the pulse signal is less than 100 milliseconds, but is not limited to such. In some embodiments, an electrical current associated with the pulse signal exceeds about 50 amperes, but is not limited to such.

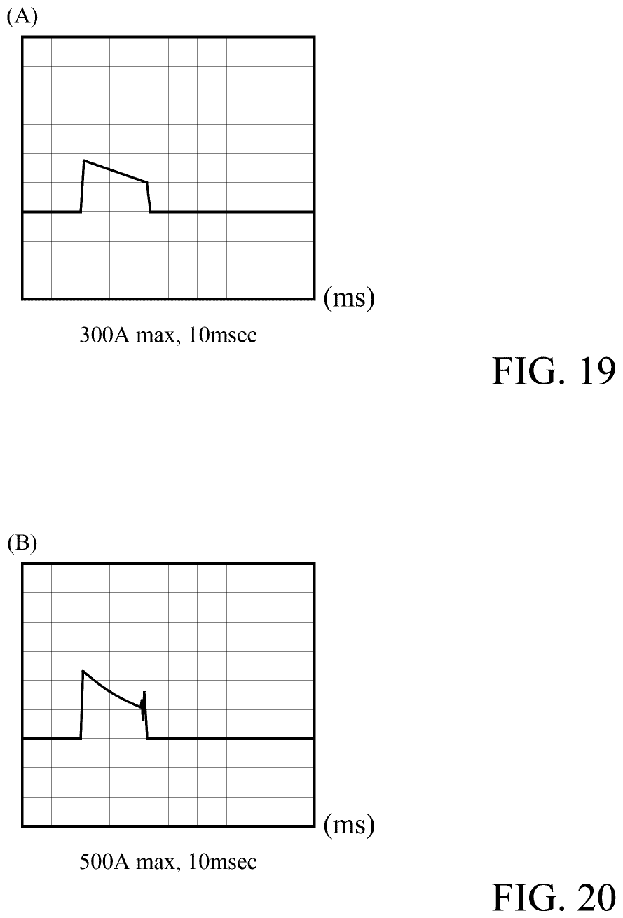

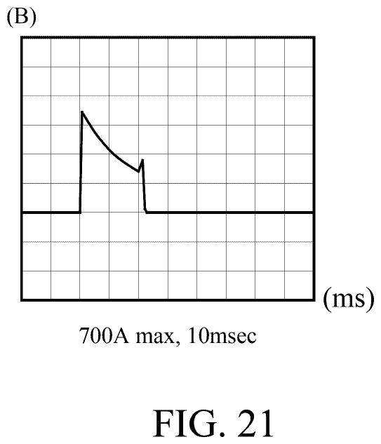

A number of exemplary pulse signal may have the waveform as shown in FIGS. 19 to 21, with different electrical current associated with the pulse signal. In some embodiments, the duration between rising and falling edges of each pulse of the pulse signal is less than 20 milliseconds. In some alternative embodiments, the duration between rising and falling edges of each pulse of the pulse signal is less than 10 milliseconds. In some embodiments, an electrical current associated with the pulse signal exceeds about 100 amperes. In some embodiments, an electrical current associated with the pulse signal exceeds about 300 amperes, but is not limited to such.

Then, in step 506, after the first subset 314A of the heating set 314 has switched to the standby state, the power supply and control module 330 is connected via the switch 325 to the second subset 314, and activates the second subset 314B of the heating set 314 (i.e., the switch 338 is switched to the second position), so as to cause the second subset 314B of the heating set 314 to switch to an activated state (i.e., to ignite the flash lamp 315 of the second subset 314B) and in turn heat the parts of the substrate 350 that correspond with the second subset 314B (i.e., below the second subset 314B). In some embodiments, an electrical current caused by the operation of step 506 exceeds about 50 amperes, but is not limited to such. That is to say, the power supply and control module 330 activates second subset 314B of the heating set 314, thereby switching the second subset 314B to the activated state to heat the corresponding parts of the substrate 350.

Then, in step 508, the power supply and control modules 330 deactivates the second subset 314B of the heating set 314 (i.e., the switch 338 is switched to the first position), so as to cause the second subset 314B of the heating set 314 to switch to the standby state (i.e., cause the flash lamp 315 to turn off) and stop heating the parts of the substrate that correspond with the second subset 314B. That is to say, the power supply and control module 330 deactivates the second subset 314B of the heating set 314, thereby switching the second subset 314B to the standby state to stop heating the corresponding parts of the substrate 350.

It is noted that the consecutive execution of steps 506 and 508 is equivalent to providing another pulse signal fed to the second subset 314B to heat the corresponding parts of the substrate 350. In some embodiments, a duration between rising and falling edges of each pulse of the another pulse signal is less than 100 milliseconds, but is not limited to such. In some embodiments, an electrical current associated with the another pulse signal exceeds about 50 amperes, but is not limited to such.

Similar to the operations of steps 502 and 504, a number of exemplary pulse signal provided in steps 506 and 508 may have the waveforms as shown in FIGS. 19 to 21, with different electrical current associated with the pulse signal. In some embodiments, the duration between rising and falling edges of each pulse of the pulse signal is less than 20 milliseconds. In some alternative embodiments, the duration between rising and falling edges of each pulse of the pulse signal is less than 10 milliseconds. In some embodiments, an electrical current associated with the pulse signal exceeds about 100 amperes. In some embodiments, an electrical current associated with the pulse signal exceeds about 300 amperes, but is not limited to such.

As such, the flash lamp annealing operation of the substrate 350 is completed.

Some advantages may be derived using the above manner to implement the flash lamp annealing operation. First, by separately heating different parts of the substrate 350, a requirement of the capacitance for the capacitor 334 may be reduced since the electrical energy needed for heating the parts of the substrate 350 is less than the electrical energy needed for heating the entirety of the substrate 350. As such, this configuration may achieve the desired low thermal budget brought by flash lamp annealing without employing a large stack of capacitors. Furthermore, by separately heating different parts of the substrate 350, the thermal stress induced on the substrate 350 by the heating may also be reduced, therefore eliminating the potential issue of damaging the transistors on the substrate 350.

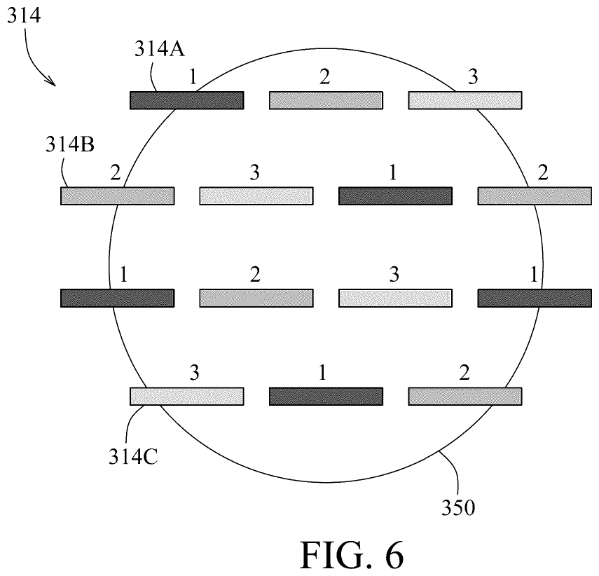

According to one embodiment of the disclosure, the heating set 314 includes a first subset 314A, a second subset 314B and a third subset 314C. The first subset 314A, the second subset 314B and the third subset 314C are disposed spaced apart from one another, and each include a plurality of flash lamps that are arranged in a staggering manner. FIG. 6 is a top view illustrating an exemplary arrangement of the first subset 314A (with the flash lamps labeled 1), the second subset 314B (with the flash lamps labeled 2) and the third subset 314C (with the flash lamps labeled 3) that are disposed to be on top of a substrate 350. That is to say, each subset corresponds to different parts of the substrate 350. In the embodiment of FIG. 6, each of the first subset 314A, the second subset 314B and the third subset 314C includes five flash lamps. It is noted that in other embodiments, other arrangements for the first subset 314A, the second subset 314B and the third subset 314C may be employed, and are not limited to the arrangement shown in FIG. 6.

Five power supply and control modules 330 may be provided, each being similar to the power supply and control module 330 shown in FIG. 4 and being connected to a respective one of the flash lamps in each of the first subset 314A, the second subset 314B and the third subset 314C via a three-way switch unit 325 that can be operated between a first state in which the power supply and control module 330 is connected to the respective one of the flash lamps of the first subset 314A, a second state in which the power supply and control module 330 is connected to the respective one of the flash lamps of the second subset 314B, and a third state in which the power supply and control module 330 is connected to the respective one of the flash lamps of the third subset 314C. It is noted that in other embodiments, different numbers of power supply and control modules 330 may be provided based on the number of the flash lamps included in each of the first subset 314A, the second subset 314B and the third subset 314C, and is not limited to the configuration as shown in FIG. 6.

It is noted that in some embodiments, the power supply and control module 330 may employ circuit structures other than the one shown in FIG. 4. For example, in some embodiments, the power supply and control module 330 may further include a pulse generator connected to the transformer 342.

In use, the flash lamp annealing operation may be implemented in a manner similar as that shown in the method of FIG. 5. Specifically, after the flash lamp annealing operation is initiated, operations of steps 502 to 508 may be implemented, that is, the first subset 314A is first activated in step 502, and the flash lamps labeled 1 in FIG. 6 are ignited, heating the corresponding parts of the substrate 350 below. Then, the first subset 314A is deactivated and switches to the standby state in step 504. After that, the second subset 314B is activated in step 506, and the flash lamps labeled 2 in FIG. 6 are ignited, heating the corresponding parts of the substrate 350 below. Then, the second subset 314B is deactivated and switches to the standby state in step 508.

Afterward, the third subset 314C is activated, thereby switching the third subset to an activated state (i.e., the flash lamps labeled 3 in FIG. 6 are ignited), heating the corresponding parts of the substrate 350 below. Then, the third subset 314C is deactivated and switches to the standby state to stop heating the corresponding parts of the substrate. As such, the flash lamp annealing operation of the substrate 350 is completed.

In some embodiments, the flash lamp annealing operation may be iterated multiple times depending on different applications. In use, the annealing apparatus 300 may further include a sensor module (not depicted in the drawings) connected to the power supply and control module 330, and the power supply and control module 330 is configured to determine, after the flash lamp annealing operation of the substrate 350 is completed, whether the flash lamp annealing operation is to be iterated based on a predetermined condition, and in the case that it is determined the flash lamp annealing operation is to be iterated, the flow goes back to step 502 to repeat the flash lamp annealing operation again. Specifically, in some embodiments, after one flash lamp annealing operation is completed, some electrical characteristics of the surface of the substrate 350 may be tested to determine whether the predetermined condition is met (e.g., the electrical characteristics of the surface of the substrate 350 is as intended).

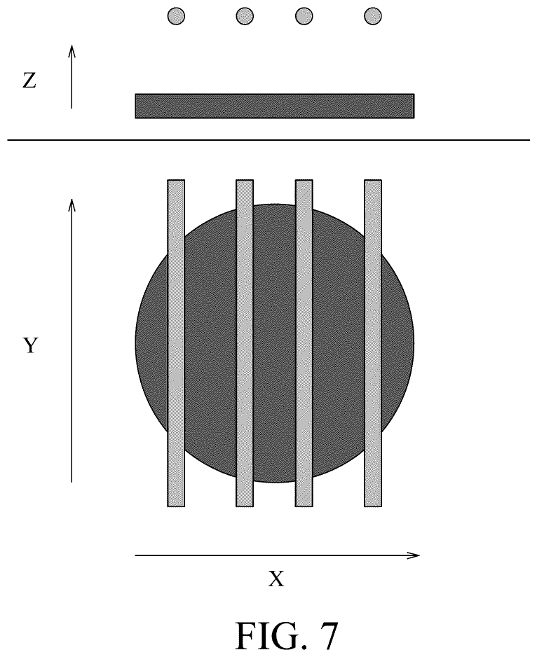

FIG. 7 is a top view illustrating an exemplary configuration of the heating set 314 according to one embodiment of the disclosure. In the embodiment of FIG. 7, the heating set 314 includes a first subset 314A, a second subset 314B, a third subset 314C, and a fourth subset 314D. Each of the first subset 314A, the second subset 314B, the third subset 314C and the fourth subset 314D may be embodied using one flash lamp. Each flash lamp may be cylindrical in shape, and the flash lamps may be arranged in a row with respect to a horizontal plane and spaced apart from one another by about 7.5 to about 10.5 centimeters. Each flash lamp may be configured to emit light in a uniform manner, with an identical relative intensity of light, and may be disposed such that when the substrate 350 is placed on the base 312, a distance between the heating set 314 above a surface of the substrate 350 is about 3 to about 5 centimeters.

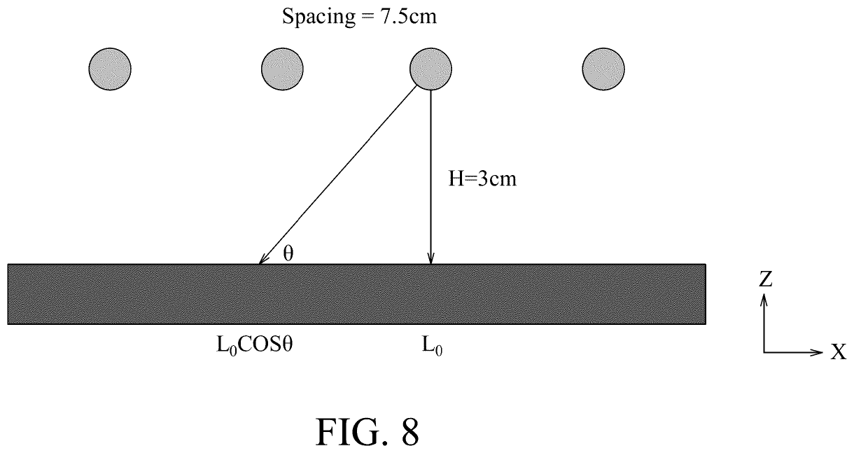

FIG. 8 is a side view illustrating an exemplary arrangement of the heating set 314 in which the flash lamps are spaced apart from one another by 7.5 centimeters and are 3 centimeters above the surface of the substrate 350.

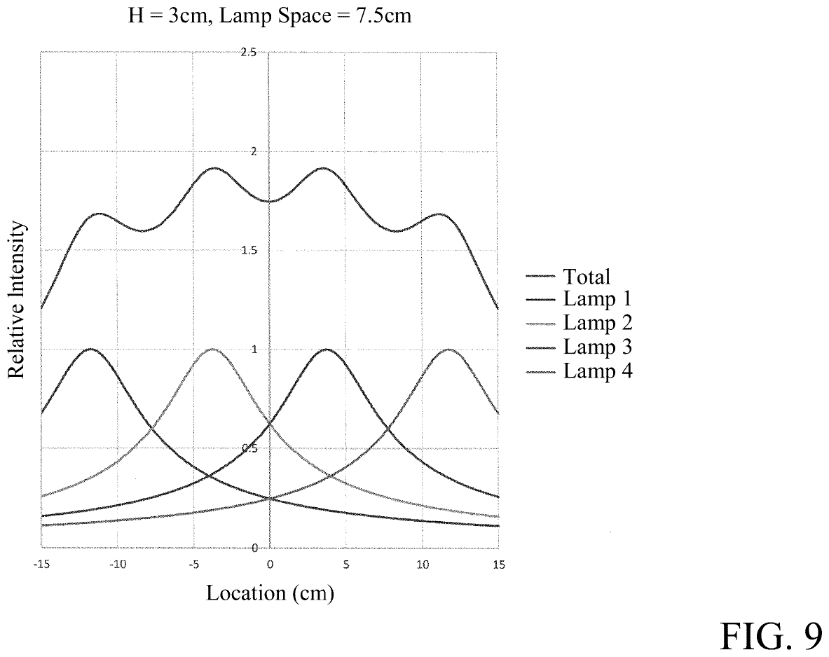

FIG. 9 illustrates the relative intensity of light emitted onto the surface of the substrate 350 by the heating set 314 of FIG. 8. In the example of FIG. 8, each of the first subset 314A, the second subset 314B, the third subset 314C and the fourth subset 314D is embodied using a same flash lamp. The relative intensity of light of each of the flash lamps may have a same default value.

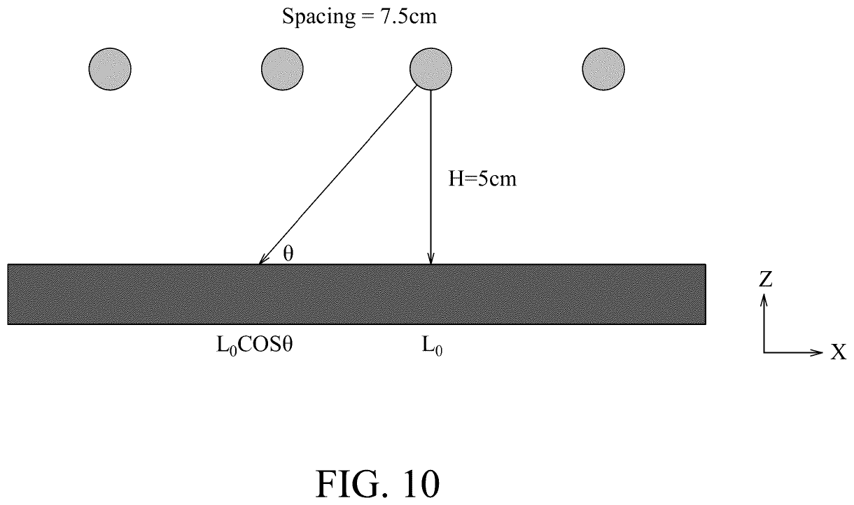

FIG. 10 is a side view illustrating an exemplary arrangement of the heating set 314 in which the flash lamps are spaced apart from one another by 7.5 centimeters and are 5 centimeters above the surface of the substrate 350.

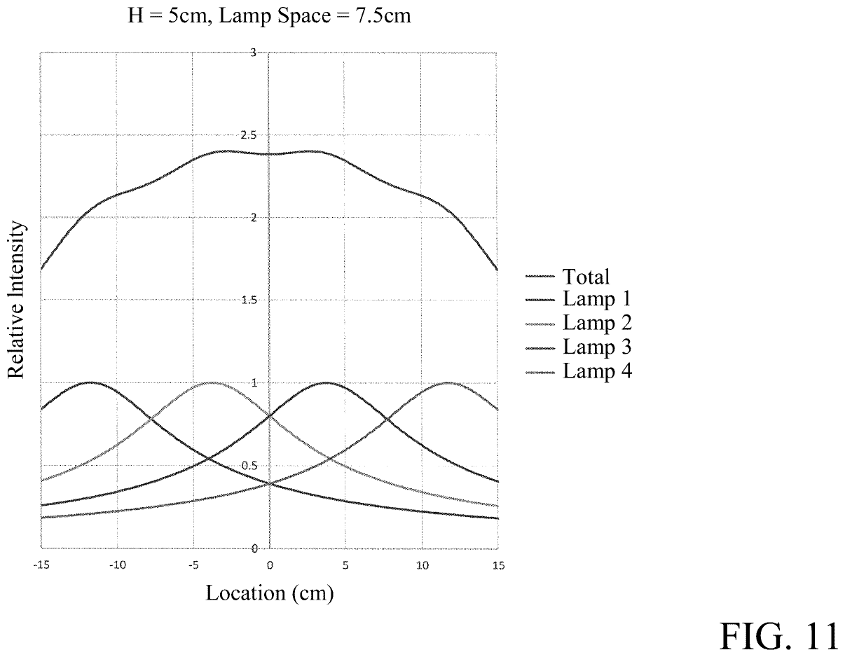

FIG. 11 illustrates the relative intensity of light emitted onto the surface of the substrate 350 by the heating set 314 of FIG. 10. In the example of FIG. 10, each of the first subset 314A, the second subset 314B, the third subset 314C and the fourth subset 314D is embodied using a same flash lamp. It is evident from FIGS. 9 and 11 that a change in the distance between the heating set 314 and the surface of the substrate 350 would cause a change in the profile of the total relative intensity of light emitted onto the surface of the substrate 350, and therefore the uniformity of heating would vary.

It is noted that in some embodiments, in an application that requires the relative intensity of light to be more uniformly distributed on the surface of the substrate 350, the heating set 314 may be modified.

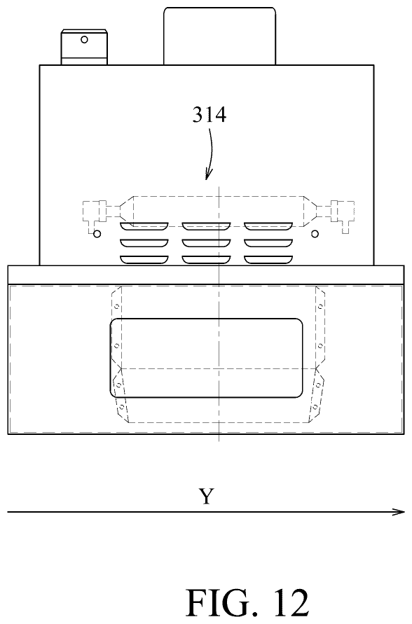

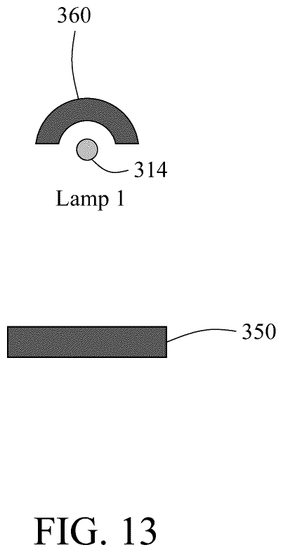

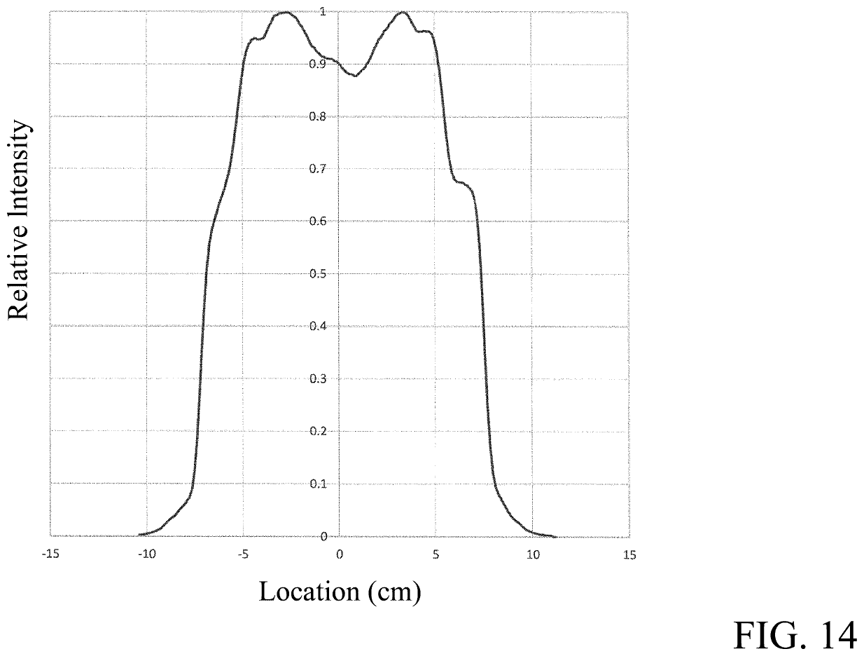

FIG. 12 illustrates an exemplary heating set 314 that includes one flash lamp for the purpose of illustration. FIG. 13 illustrates an exemplary configuration of the heating set 314 and a secondary optical adjustment module 360 according to one embodiment of the disclosure. The secondary optical adjustment module 360 is positioned above the heating set 314, and includes a reflection mirror positioned above the flash lamp of the heating set 314. The reflection mirror is shaped to reflect the light emitted by the flash lamp, and because of the effect of secondary optical adjustment provided by the reflection mirror, the light may be directed to and converge on the surface of the substrate 350. FIG. 14 illustrates the relative intensity of light emitted onto the surface of the substrate 350 by the heating set 314 and the secondary optical adjustment module 360 of FIG. 13. It can be seen that the relative intensity is largely uniformly confined within 10 centimeters with respect to the horizontal plane, and is nearly undetected from 20 centimeters away.

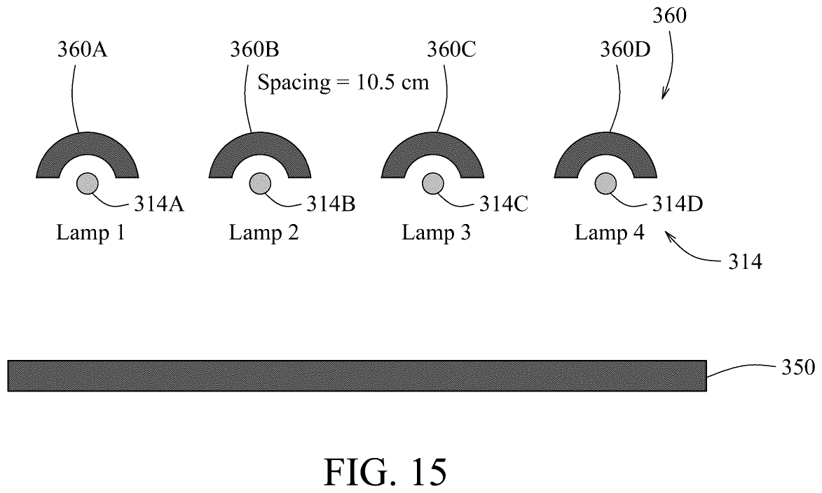

FIG. 15 illustrates an exemplary configuration of the heating set 314 with the secondary optical adjustment module 360 provided according to one embodiment of the disclosure. In the example of FIG. 15, the heating set 314 includes the first subset 314A, the second subset 314B, the third subset 314C and the fourth subset 314D, and the secondary optical adjustment module 360 includes four reflection mirrors (labelled as 360A, 360B, 360C and 360D, respectively) that are disposed above a respective one of the first subset 314A, the second subset 314B, the third subset 314C and the fourth subset 314D. In the embodiment of FIG. 15, each of the first subset 314A, the second subset 314B, the third subset 314C and the fourth subset 314D is spaced apart from one another by about 10.5 centimeters, and is above the surface of the substrate 350 by about a predetermined distance. It is noted that with different flash lamps and different applications for heating the substrate 350, different setups of the heating set 314 may be employed.

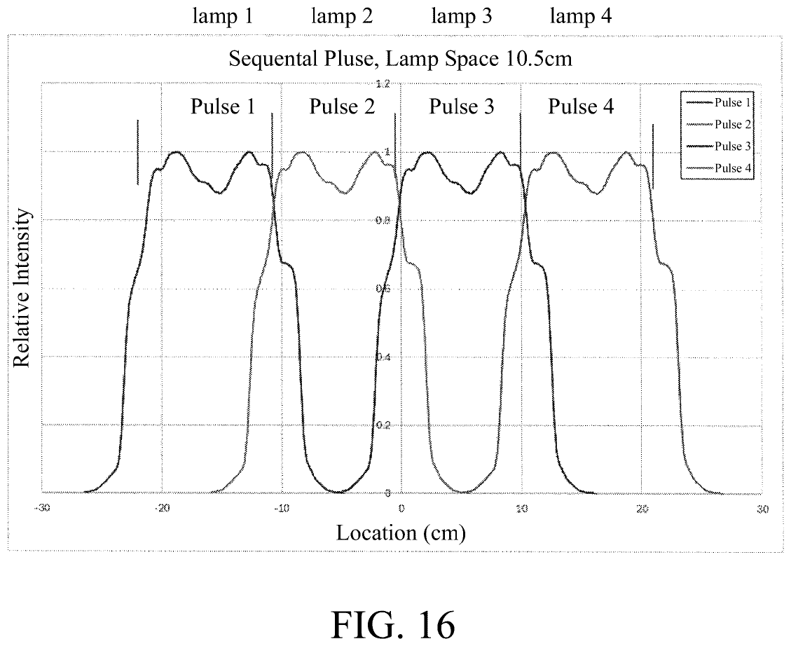

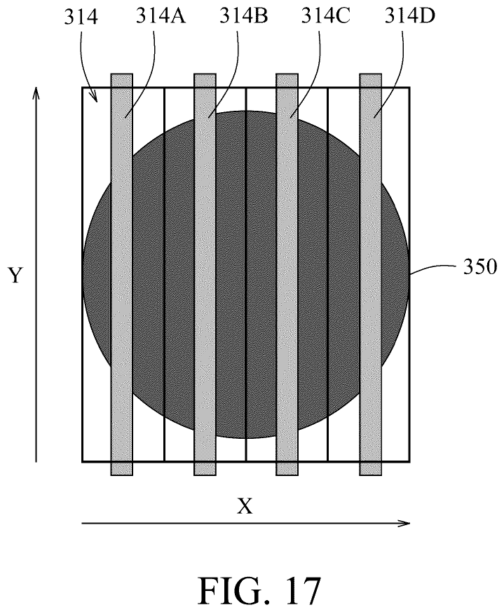

FIG. 16 illustrates the relative intensity of light emitted onto the surface of the substrate 350 by the heating set 314 and the secondary optical adjustment module 360 of FIG. 15. FIG. 17 is a top view illustrating the heating set 314 and the secondary optical adjustment module 360 of FIG. 15 disposed above the substrate 350. It can be seen that since the relative intensity attributed to each of the first subset 314A, the second subset 314B, the third subset 314C and the fourth subset 314D is similar (i.e., confined uniformly within about 10 centimeters). That is to say, by designing the distance between adjacent two subsets at 10.5 centimeters, the light emitted by one subset substantially does not reach a part of the surface of the substrate 350 associated with the other subset. As such, the configuration of FIG. 15 may achieve a more uniformly distributed relative intensity of light on the entirety of the surface of the substrate 350.

Is it noted that for the example of FIG. 15, the first subset 314A, the second subset 314B, the third subset 314C and the fourth subset 314D may be separately activated (not necessarily in a particular order), or may be activated simultaneously, depending on different applications.

To sum up, the embodiments of the disclosure provide an annealing apparatus and a method for operating the annealing apparatus for performing a flash lamp annealing operation. The annealing apparatus includes a heating set that includes at least a first subset and a second subset. Each of the first subset and the second subset is disposed such that when a substrate is placed on a base of the annealing apparatus, the first subset and a second subset correspond with different parts of a surface of the substrate. In performing the flash lamp annealing operation on the surface of the substrate, a power supply and control module first activates the first subset of the heating set, so as to cause the first subset of the heating set to switch to an activated state and heat the parts of the substrate that correspond with the first subset, and the power supply and control module then deactivates the first subset of the heating set, so as to cause the first subset of the heating set to switch to a standby state and stop heating the parts of the substrate that correspond with the first subset. Then, the power supply and control module first activates the second subset of the heating set, so as to cause the second subset of the heating set to switch to the activated state and heat the parts of the substrate that correspond with the second subset, and the power supply and control module then deactivates the second subset of the heating set, so as to cause the second subset of the heating set to switch to the standby state and stop heating the parts of the substrate that correspond with the second subset.

The embodiments provide some advantages. For example, by separately heating different parts of the substrate, a requirement of the capacitance of a capacitor used for storing electrical energy may be reduced since the electrical energy needed for heating the parts of the substrate is less than the electrical energy needed for heating the entirety of the substrate. As such, this configuration may achieve the desired lower thermal budget brought by flash lamp annealing in comparison to conventional annealing without employing a large stack of capacitors. Furthermore, by separately heating different parts of the substrate, the thermal stress induced on the substrate by the heating may also be reduced, therefore eliminating the potential issue of damaging the transistors on the substrate.

The configurations of the annealing apparatus and a method for operating the annealing apparatus for performing a flash lamp annealing operation are particularly useful in the cases that the scales of the semiconductor devices to be manufactured on the substrate continue to shrink. In the case that it is intended to heat up only a few nanometers below the surface of the substrate, a duration of the pulse signal is as short as possible (e.g., less than 20 milliseconds) to prevent thermal conduction, and therefore a relatively large electrical current (e.g., larger than 300 amperes) is needed to achieve the heating effect in such a short duration. With reference to FIG. 16, the larger the electrical current is intended, an exponentially larger voltage (and therefore, electrical power and the electrical energy stored in the capacitor) is needed.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. An annealing apparatus comprising:
a chamber;
a base disposed in the chamber for supporting a substrate;
a heating set disposed in the chamber above the base, the heating subset including at least a first subset and a second subset, each subset configured to correspond to different parts of the substrate disposed on the base; and
a power supply and control module connected to the heating set and configured to control its operations,
wherein the power supply and control module is configured to:
activate the first subset of the heating set, thereby switching the first subset to an activated state to heat the corresponding parts of the substrate,
deactivate the first subset of the heating set, thereby switching the first subset to a standby state to stop heating the corresponding parts of the substrate,
activate the second subset of the heating set, thereby switching the second subset to an activated state to heat the corresponding parts of the substrate, and
deactivate the second subset of the heating set, thereby switching the second subset to a standby state to stop heating the corresponding parts of the substrate;
wherein:
activating and deactivating of the first subset are controlled by providing a pulse signal to the first subset;
activating and deactivating of the second subset are controlled by providing another pulse signal to the second subset.

2. The annealing apparatus as claimed in claim 1, wherein each of the first subset and the second subset includes a flash lamp, and the first subset and the second subset are spaced apart from each other.

3. The annealing apparatus as claimed in claim 2, further comprising a switch configured to connect the power supply and control module to the first subset and the second subset of the heating set, the switch being operated between: a first state, in which the power supply and control module is connected to the flash lamp of the first subset; and a second state, in which the power supply and control module is connected to the flash lamp of the second subset.

4. The annealing apparatus as claimed in claim 2, wherein the flash lamp of each of the first subset and the second subset is cylindrical in shape.

5. The annealing apparatus as claimed in claim 2, further comprising a secondary optical adjustment module positioned above the heating set.

6. The annealing apparatus as claimed in claim 5, wherein the secondary optical adjustment module comprises a plurality of reflection mirrors, each reflection mirror being positioned above a respective flash lamps of the first subset and the second subset.

7. The annealing apparatus as claimed in claim 1, wherein the power supply and control module comprises:
a charging device;
a capacitor;
an inductor connected to the heating set;
a switch connected to the charging device, the capacitor, and the inductor,
the switch being operable between:
a first position, in which the charging device is connected to the capacitor to charge it; and
a second position, in which the capacitor is connected to the inductor; and
a simmer power supplying component connected to the heating set;
wherein, when the switch is in the second position, energy stored in the capacitor is transferred to the heating set, thereby activating one of the first subset or the second subset of the heating set.

8. The annealing apparatus as claimed in claim 1, wherein:
the heating set further comprises a third subset connected to the power supply and control module, each of the first subset, the second subset, and the third subset comprising a plurality of flash lamps that are spaced apart from one another, each subset corresponding to different parts of the substrate; and
the power supply and control module is further configured to:
after deactivating the second subset, activate the third subset of the heating set, thereby switching the third subset to an activated state to heat the corresponding parts of the substrate; and
deactivate the third subset of the heating set, thereby switching the third subset to a standby state to stop heating the corresponding parts of the substrate.

9. The annealing apparatus as claimed in claim 1, wherein:
the duration between rising and falling edges of each pulse of the pulse signal is less than 20 milliseconds; and
the duration between rising and falling edges of each pulse of the another pulse signal is less than 20 milliseconds.

10. The annealing apparatus as claimed in claim 1, wherein:
the duration between rising and falling edges of each pulse of the pulse signal is less than 10 milliseconds; and
the duration between rising and falling edges of each pulse of the another pulse signal is less than 10 milliseconds.

11. The annealing apparatus as claimed in claim 1, wherein:
an electrical current associated with the pulse signal exceeds 100 amperes, and an electrical current associated with the another pulse signal exceeds 100 amperes.

12. The annealing apparatus as claimed in claim 1, wherein:
an electrical current associated with the pulse signal exceeds 300 amperes, and an electrical current associated with the another pulse signal exceeds 300 amperes.

13. A method for operating an annealing apparatus, the annealing apparatus comprising a chamber, a base disposed in the chamber for supporting a substrate, a heating set disposed in the chamber and above the base and including at least a first subset and a second subset, each subset corresponding to different parts of the substrate disposed on the base, and a power supply and control module connected to the heating set to control its operation, the method being implemented by the power supply and control module and comprising:
activating the first subset of the heating set to switch the first subset to switch to an activated state and heat the parts of the substrate corresponding to the first subset;
deactivating the first subset of the heating set to switch the first subset to a standby state and stop heating the parts of the substrate corresponding to the first subset;
activating the second subset of the heating set to switch the second subset to an activated state and heat the parts of the substrate corresponding to the second subset; and
deactivating the second subset of the heating set to switch the second subset to a standby state and stop heating the parts of the substrate that corresponding to the second subset;
wherein:
the consecutive operations of activating and deactivating the first subset are performed by providing a pulse signal to the first subset;
the consecutive operations of activating and deactivating the second subset are performed by providing another pulse signal to the second subset.

14. The method as claimed in claim 13, wherein each of the first subset and the second subset comprises a flash lamp, and the first subset and the second subset are spaced apart from each other, wherein:
activating the first subset includes providing a pulse signal to the flash lamp of the first subset; and
activating the second first subset includes providing a pulse signal to the flash lamp of the second subset.

15. The method as claimed in claim 13, wherein the annealing apparatus further comprises a switch configured to connect the power supply and control module to the first subset and the second subset of the heating set, the switch being operable between:
a first state, in which the power supply and control module is connected to the flash lamp of the first subset; and
a second state, in which the power supply and control module is connected to the flash lamp of the second subset;
wherein:
activating the first subset of the heating set includes switching the switch to the first state; and
activating the second subset of the heating set includes switching the switch to the second state.

16. The method as claimed in claim 13, wherein:
the duration between the rising and falling edges of each pulse of the pulse signal is less than 20 milliseconds; and
the duration between rising and falling edges of each pulse of the another pulse signal is less than 20 milliseconds.

17. The method as claimed in claim 13, wherein:
the duration between the rising and falling edges of each pulse of the pulse signal is less than 10 milliseconds; and
the duration between rising and falling edges of each pulse of the another pulse signal is less than 10 milliseconds.

18. The method as claimed in claim 13, wherein:
an electrical current associated with the pulse signal exceeds 100 amperes, and an electrical current associated with the another pulse signal exceeds 100 amperes.

19. The method as claimed in claim 13, wherein:
an electrical current associated with the pulse signal exceeds 300 amperes, and an electrical current associated with the another pulse signal exceeds 300 amperes.

20. The method as claimed in claim 13, wherein the heating set further comprises a third subset connected to the power supply and control module, each of the first subset, the second subset, and the third subset comprising a plurality of flash lamps being spaced apart from one another, with each subset corresponding to different parts of the substrate, the method further comprising:
after deactivating the second subset:
activating the third subset to switch the third subset to an activated state and heat the parts of the substrate corresponding to the third subset; and
deactivating the third subset to switch the third subset to a standby state and stop heating the parts of the substrate corresponding to the third subset.

21. The method as claimed in claim 13, further comprising, prior to activating the first subset, providing a secondary optical adjustment module above the heating set.

22. The method as claimed in claim 13, wherein the secondary optical adjustment module comprises a plurality of reflection mirrors, each reflection mirror being positioned above a respective flash lamp of the first subset and the second subset.

23. The method as claimed in claim 13, wherein the power supply and control module comprises:
a charging device,
a capacitor,
an inductor connected to the heating set,
a switch connected to the charging device, the capacitor, and the inductor, the switch being operable to:
a first position, in which the charging device is connected to the capacitor to charge it, and
a second position, in which the capacitor is connected to the inductor, and
a simmer power supplying component connected to the heating set,
wherein, when the switch is in the second position, energy stored in the capacitor is transferred to the heating set to activate one of the first subset or the second subset of the heating set.
